(19) United States
(12) Patent Application Publication
(10) Pub. No.: US 2019/0067505 A1
(43) Pub. Date: Feb. 28, 2019

(54) SOLAR CELL PANEL AND THE WINDOW COMPRISING THE SAME

(71) Applicant: KOREA INSTITUTE OF SCIENCE AND TECHNOLOGY, Seoul (KR)

(72) Inventors: Hyungduk KO, Seoul (KR); Il Ki Han, Seoul (KR); Ho Seong Jang, Seoul (KR)

(73) Assignee: KOREA INSTITUTE OF SCIENCE AND TECHNOLOGY, Seoul (KR)

(21) Appl. No.: 15/792,478

(22) Filed: Oct. 24, 2017

(30) Foreign Application Priority Data
Aug. 30, 2017 (KR) 10-2017-0110406

(51) Int. Cl. H01L 31/054; H01L 31/043; H01L 31/05

(52) U.S. Cl. CPC H01L 31/0543; H01L 31/05; H01L 31/043; H01L 31/0547

(57) ABSTRACT

A solar cell panel includes a light concentration layer on which sunlight is incident and concentrated; a cladding layer stacked on bottom of the light concentration layer; a light conversion/light guide layer including a light guide layer stacked on bottom of the light concentration layer to guide visible light to a side surface and a light conversion member to convert ultraviolet or infrared light to visible light; and a solar cell array placed along a side surface of the light conversion/light guide layer and having multiple solar cells electrically connected. The solar cell panel and a window comprising the same can increase efficiency of a window-type solar module by converting and concentrating light in a wavelength range not contributing to solar cell efficiency.

### CROSS-REFERENCE TO RELATED APPLICATIONS

This application claims priority under 35 U.S.C. § 119 to Korean Patent Application No. 10-2017-0110406 filed on Aug. 30, 2017 in the Korean Intellectual Property Office, the disclosure of which is incorporated herein by reference in its entirety.

### TECHNICAL FIELD

The present disclosure relates to a solar cell panel and a window comprising the same, and more particularly, to a solar cell panel that effectively concentrates incident sunlight on a side panel frame by taking advantage of technology convergence for light guide and concentration, light conversion and solar cell technology systems, thereby improving solar cell efficiency, and a window comprising the same.

### BACKGROUND

Recently, solar power plants that produce electricity using solar energy are gradually coming into widespread use. Solar cells using solar energy are gaining much attention as a new alternative energy source of the future because they do not use fossil fuels such as coal or petroleum, generate no pollution and use abundant sunlight as an energy source, and currently, they are being used in obtaining electrical power for solar power plants, buildings or vehicles.

Solar power generation has a wide range of applications, and among them, building integrated photovoltaic (BIPV) technology using solar cells for the skin of buildings is recently gaining attention as a promising new technology in the 21st century around the world. The building integrated photovoltaics are an innovative technology involving the evolution of ordinary building envelopes as a tool for creating energy beyond the viewpoint of protection concept from external stimulation, and because solar cells can play a role in the power demand and supply, it is expected to have a dual effect, together with the savings of costs spent on installing conventional solar power generating systems.

One of the integration of solar cells into building envelopes is solar windows with solar cells integrated into windows. All buildings are required to be zero-energy around the world including Republic of Korea by 2020, and accordingly, there is an emerging need for building's self-energy production technology such as solar windows.

To apply solar windows to buildings, large-scale high-efficiency solar cell technology for windows with the combination of aesthetics and function and high stability for a long time is required. However, a conventional solar window is simply constructed by inserting a solar module into a pair of glass substrates or attaching a solar module to one surface of a glass substrate, and the downside is that it has low efficiency and visibility and it is unsuitable for large-scale windows.

### RELATED LITERATURES

### Patent Literatures

WO 2015/079094

### Non-Patent Literatures

Optimisation of a three-colour luminescent solar concentrator daylighting system, Solar Energy Materials & Solar Cells 84 (2004) 411-426

### SUMMARY

The present disclosure is directed to providing a solar cell panel in which light in a wavelength range not contributing to solar cell efficiency is converted and concentrated to increase efficiency of a window-type solar module, and to solve the problem with self-absorption phenomenon of a light conversion material in conventional luminescent solar concentrator (LSC) modules, only an area on which light is concentrated is coated with an ultraviolet conversion material to minimize self-absorption phenomenon, and besides, an infrared conversion material is positioned on the side surface to effectively convert infrared light concentrated onto the side surface, thereby improving optical efficiency, and a window comprising the same.

According to an aspect of the present disclosure, there is provided a solar cell panel including: a light concentration layer on which sunlight is incident and concentrated; a cladding layer stacked on bottom of the light concentration layer; a light conversion/light guide layer including a light guide layer stacked on bottom of the cladding layer to guide visible light to a side surface and a light conversion member to convert ultraviolet or infrared light to visible light; and a solar cell array placed along a side surface of the light conversion/light guide layer and having multiple solar cells electrically connected.

The light concentration layer may include any one selected from a convex lens, a concave lens, and a Fresnel lens.

The protrusion structure may be a conical structure.

The distance between top edges of the protrusions formed on the pattern layer may be between 350 and 530 nm.

The cladding layer may have a refractive index n of between 1.0 and 1.3.

The light conversion member may include: a first light conversion member to convert ultraviolet light to visible light; and a second light conversion member to convert infrared light to visible light.

Preferably, the first light conversion member may be disposed on top or bottom or in the middle of the light guide layer, and may include: a light conversion layer including a downconversion material to convert ultraviolet light to visible light; and a reflective layer stacked on bottom of the light conversion layer or spaced apart from the light conversion layer.

The light conversion layer may be disposed on a focal plane or off the focal plane.

The downconversion material may be at least one selected from quantum dot, phosphor, and ultraviolet conversion dye.

The quantum dot may be at least one selected from CdZnS/ZnS, CdS, CdSe, CdSe/ZnS, PbS, CdTe, ZnS, ZnSe, ZnTe, GaN, GaP, GaAs, GaSb, AlN, AlP, AlAs, AlSb, InP, InAs, InSb and SiC.

The phosphor may be at least one selected from β-NaYF₄:Yb³⁺/Er³⁺, Y₃Al₅O₁₂:Ce, Y₂SiO₅:Ce³⁺, Sr₂SiO₄:Eu²⁺, Sr₃SiO₅:Eu²⁺, BaMaAl₁₀O₁₇:Eu²⁺, Y₂O₃:Eu³⁺, Y₂O₂S:Eu³⁺, Y₂O₃:Eu³⁺, Bi³⁺, CaMgSi₂O₇:Eu²⁺, SrGa₂S₄:Eu²⁺, Ca-a-SiAlON:Eu²⁺, BaSi₂O₂N₂:Eu²⁺, and CaGa₂S₄:Eu²⁺.

The second light conversion member may be disposed on a side surface of the light guide layer.

The second light conversion member may include an upconversion material.

The upconversion material may be at least one selected from halide, chalcogenide and metal oxide doped with ytterbium (Yb), erbium (Er), thulium (Tm), yttrium (Y) or mixtures thereof.

According to another aspect of the present disclosure, there is provided a window comprising a solar cell panel, including: the solar cell panel; and a frame connected along edges of the solar cell panel.

The solar cell array may be placed on the frame, and the frame may be disposed on at least one side surface of the solar cell panel.

The solar cell array placed on the frame may have an array of either a series structure or a parallel structure or both.

The frames may have an array of either a series structure or a parallel structure or both.

The solar cell panel of the present disclosure and the window comprising the same can increase efficiency of a window-type solar module by converting and concentrating light in a wavelength range not contributing to solar cell efficiency, and to solve the problem with self-absorption phenomenon of a light conversion material in conventional LSC modules, and they have a coating of ultraviolet conversion material on only an area on which light is concentrated, thereby minimizing self-absorption phenomenon, and can effectively convert infrared light concentrated onto the side surface due to an infrared conversion material positioned on the side surface, thereby improving optical efficiency.

### BRIEF DESCRIPTION OF THE DRAWINGS

FIG. 1 is a side view of a solar cell panel according to an embodiment of the present disclosure.

FIG. 2 is a side view of a solar cell panel according to another embodiment of the present disclosure.

FIG. 3 is a perspective view of a window comprising a solar cell panel according to an embodiment of the present disclosure.

FIG. 4 is a plane view and a photographic image showing a solar cell array frame structure included in a window comprising a solar cell panel according to an embodiment of the present disclosure.

FIG. 5 is a side cross-sectional view showing a solar cell array frame structure included in a window comprising a solar cell panel according to an embodiment of the present disclosure.

FIG. 6 shows an example of connection of frames including a solar cell array.

FIG. 7 shows absorption and emission spectrum of a downconversion material.

FIG. 8A shows absorption spectrum of an upconversion material.

FIG. 8B shows emission spectrum of an upconversion material.

FIG. 9 shows a concentration ratio on the side surface with the increasing window area.

### DETAILED DESCRIPTION OF EMBODIMENTS

Hereinafter, many aspects and various embodiments of the present disclosure are described in further detail.

Hereinafter, the embodiments of the present disclosure are described in sufficient detail with reference to the accompanying drawing to enable those having ordinary skill in the technical field pertaining to the present disclosure to easily practice the present disclosure.

However, the following description is not intended to limit the present disclosure to particular embodiments, and in describing the present disclosure, when a detailed description of relevant known technology is deemed to render the subject matter of the present disclosure ambiguous, its detailed description is omitted herein.

The terminology used herein is for the purpose of describing particular embodiments only and is not intended to limit the present disclosure. As used herein, the singular forms are intended to include the plural forms as well, unless the context clearly indicates otherwise. It will be further understood that the terms “comprises” or “comprising”, when used in this specification, specify the presence of stated features, integers, steps, operations, elements, or groups thereof, but do not preclude the presence or addition of one or more other features, integers, steps, operations, elements, or groups thereof.

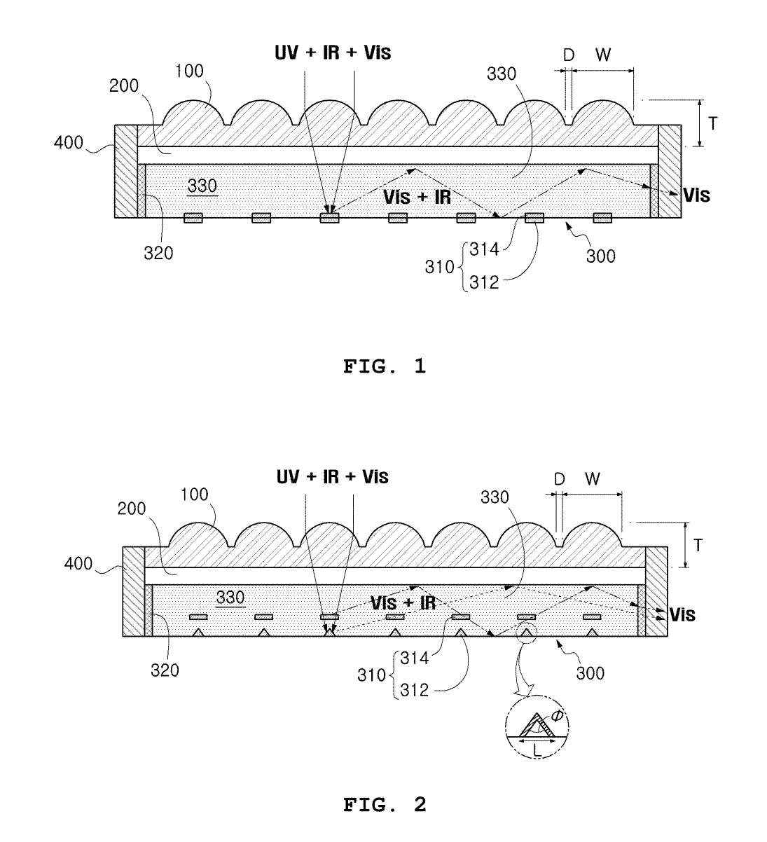

FIG. 1 is a side view of a solar cell panel according to an embodiment of the present disclosure, and FIG. 2 is a side view of a solar cell panel according to another embodiment of the present disclosure. Hereinafter, the solar cell panel of the present disclosure will be described with reference to FIGS. 1 and 2.

The solar cell panel of the present disclosure includes a light concentration layer 100, a cladding layer 200, a light conversion/light guide layer 300, and a solar cell array 400.

Specifically, the solar cell panel of the present disclosure may include: a light concentration layer 100 on which sunlight is incident and concentrated; a cladding layer 200 stacked on the bottom of the light concentration layer; a light conversion/light guide layer 300 including a light guide layer 330 stacked on the bottom of the cladding layer 200 to guide visible light to the side surface and a light conversion member 310, 320 to convert ultraviolet or infrared light to visible light; and a solar cell array 400 placed along the side surface of the light conversion/light guide layer 300 and having multiple solar cells electrically connected.

The light concentration layer 100 may include all lenses capable of concentrating light at a specific focal length, including a double-convex lens, a plano-convex lens, a double-concave lens, a plano-concave lens, and a Fresnel lens. In the drawing, the light concentration layer 100 with a plano-convex lens structure is depicted for illustration.

The plano-convex lens structure has multiple convex lens-type protrusions, preferably with the width W of each protrusion ranging between 1 and 100 mm at a distance d between the protrusions of 50 mm or less.

The thickness T of the light concentration layer 100 is preferably between 1 and 10 mm.

The cladding layer 200 may have a low refractive index n of between 1.0 and 1.3.

The light conversion member 310, 320 may include a first light conversion member 310 and a second light conversion member 320.

The first light conversion member 310 is a member which converts ultraviolet light to visible light, and the second light conversion member 320 is a member which converts infrared light to visible light.

The first light conversion member 310 is preferably disposed on the top or bottom or in the middle of the light guide layer 330, and may include a light conversion layer 314 including a downconversion material that converts ultraviolet light to visible light, and a reflective layer 312 stacked on the bottom of the light conversion layer 314 or spaced apart from the light conversion layer 314.

The reflective layer 312 may be formed with a flat structure (FIG. 1) or an inclined structure (FIG. 2).

The inclined structure may form an inclination on two side surfaces as shown in the drawing, and preferably, an angle ϕ formed by the two inclined surfaces is between 60 and 150 deg and the width L between the two inclined surfaces is between 0.5 and 5 mm. The inclined structure has an inclination on the surface where light is reflected and then guided toward the side surface of the light guide layer 330, thereby effectively inducing the total reflection.

The downconversion material may be disposed on the focal plane of incident light (see FIG. 1) or off the focal plane (see FIG. 2).

With such an arrangement, a coating of ultraviolet conversion material is applied on only an area where light is concentrated so that self-absorption phenomenon can be minimized. That is, self-absorption phenomenon of a light conversion material in conventional LSC modules can be effectively obviated.

The downconversion material may be at least one selected from quantum dot, phosphor, and ultraviolet conversion dye.

The quantum dot may be CdZnS/ZnS, CdS, CdSe, CdSe/ZnS, PbS, CdTe, ZnS, ZnSe, ZnTe, GaN, GaP, GaAs, GaSb, AlN, AlP, AlAs, AlSb, InP, InAs, InSb, and SiC.

The phosphor may be β-NaYF₄:Yb³⁺/Er³⁺, Y₃Al₅O₁₂:Ce, Y₂SiO₅:Ce³⁺, Sr₂SiO₄:Eu²⁺, Sr₃SiO₅:Eu²⁺, BaMaAl₁₀O₁₇:Eu²⁺, Y₂O₃:Eu³⁺, Y₂O₂S:Eu³⁺, Y₂O₃:Eu³⁺, Bi³⁺, CaMgSi₂O₇:Eu²⁺, SrGa₂S₄:Eu²⁺, Ca-a-SiAlON:Eu²⁺, BaSi₂O₂N₂:Eu²⁺, and CaGa₂S₄:Eu²⁺. The second light conversion member 320 is preferably disposed on the side surface of the light guide layer 330.

By virtue of an infrared conversion material positioned on the side surface, infrared light concentrated on the side surface can be effectively converted into visible light, contributing to improvement of optical efficiency.

The second light conversion member 320 may include an upconversion material.

The upconversion material may be halide, chalcogenide and metal oxide doped with ytterbium (Yb), erbium (Er), thulium (Tm), yttrium (Y) or mixtures thereof.

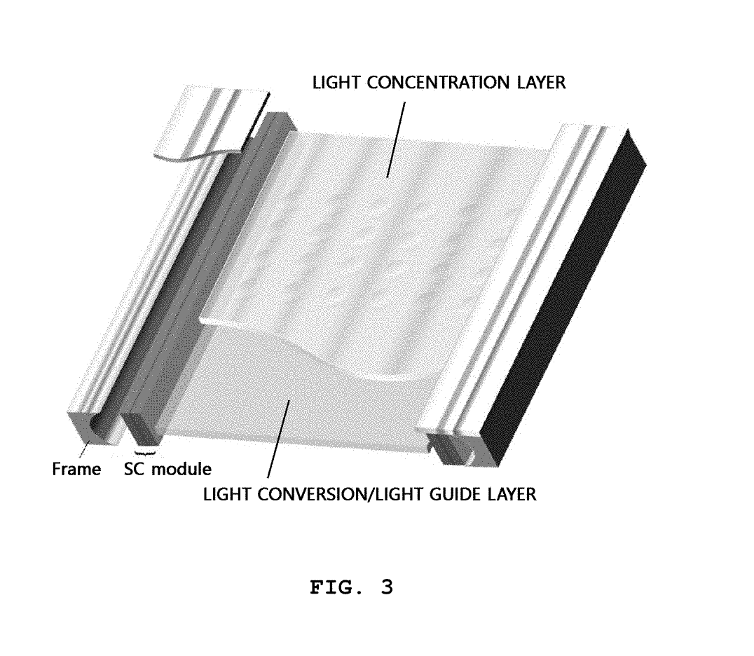

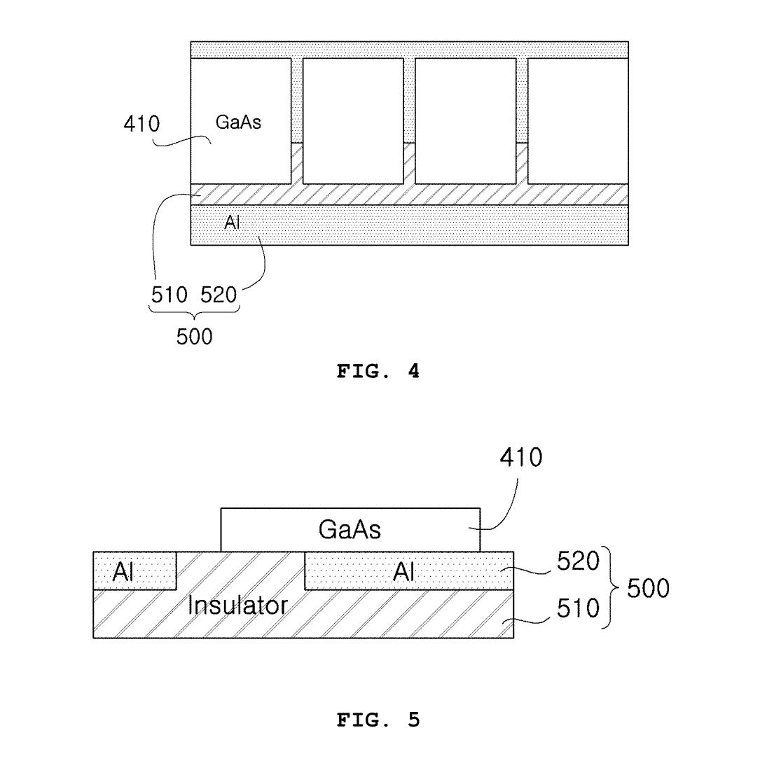

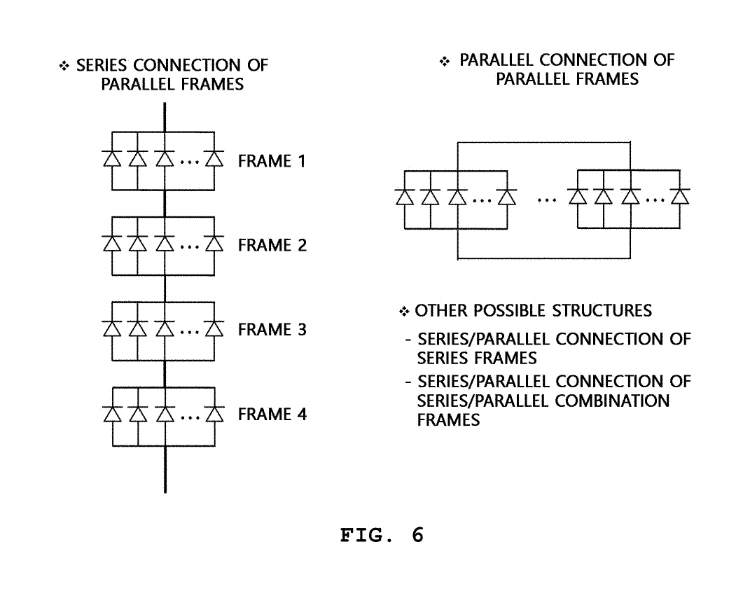

FIG. 3 is a perspective view of a window comprising the solar cell panel according to an embodiment of the present disclosure, FIG. 4 is a plane view and a photographic image showing a solar cell array frame structure included in the window comprising the solar cell panel according to an embodiment of the present disclosure, and FIG. 5 is a side cross-sectional view. Hereinafter, the window comprising the solar cell panel according to an embodiment of the present disclosure will be described with reference to FIGS. 3 to 5.

The solar cell array 400 included in this embodiment is formed along the side surface of the light conversion/light guide layer 300. Specifically, in case that the light conversion/light guide layer 300 has a four-sided plane shape, the solar cell array 400 may be provided along four side surfaces including the light conversion/light guide layer 300. The four side surfaces including the light conversion/light guide layer 300 may be the side surfaces including all of the light concentration layer 100, the cladding layer 200, and the light conversion/light guide layer 300.

Furthermore, the solar cell array 400 is placed along the side surfaces including the light conversion/light guide layer 300, and includes multiple solar cells electrically connected, and a cell frame 500 that supports the lower surface of the solar cells.

The solar cells 410 may be electrically connected in parallel or in series by wire-bonding on the upper surface of the cell frame 500. In this embodiment, the solar cells 410 may include silicon (Si)-based and gallium arsenide (GaAs)-based solar cells 410, but the scope of protection of the present disclosure is not limited thereto, and various types of known solar cells may be applied within the scope of the present disclosure.

The cell frame 500 may include an insulation layer (insulator) 510 that is placed in close contact with part of the lower surface of the solar cells 410, and a conductive layer 520 including a conducting material, for example, Al, that is placed in close contact at an area other than the area where the insulation layer 510 is placed in close contact with the lower surface of the solar cells 410.

As described above, the solar cell array 400 may be placed on the frame, and the frame may be disposed on at least one side surface of the solar cell panel.

The solar cell array 400 placed on the frame 500 may have an array of either a series structure or a parallel structure or both. Furthermore, the frames 500 may have an array of either a series structure or a parallel structure or both. An example of connection of the frames is shown in FIG. 6.

### Test Examples

Absorption and Emission Spectrum of a Downconversion Material

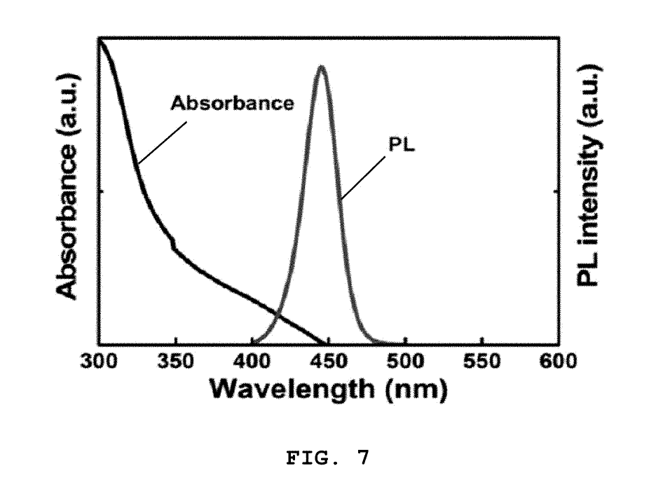

The analysis results of absorption spectrum and emission spectrum of a downconversion material, CdZnS/ZnS core/shell structured quantum dots (QDs) used in the embodiment of the present disclosure are shown in FIG. 7. According to FIG. 7, it can be seen that sunlight in the ultraviolet range is absorbed and light in the visible range is emitted.

Absorption and Emission Spectrum of an Upconversion Material

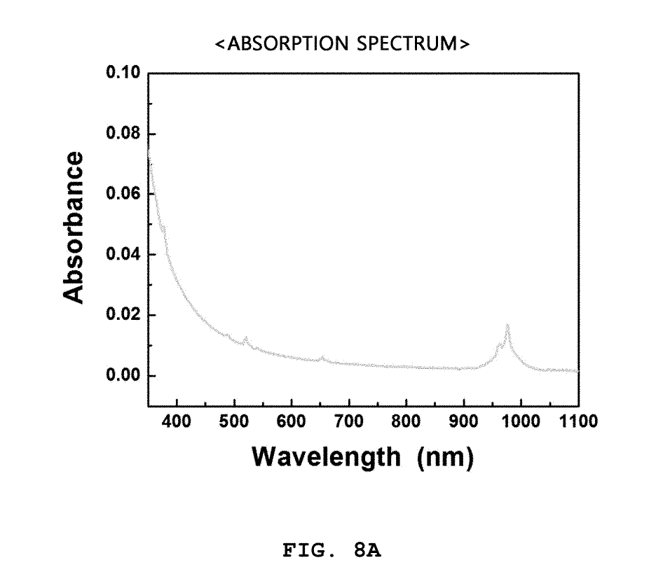

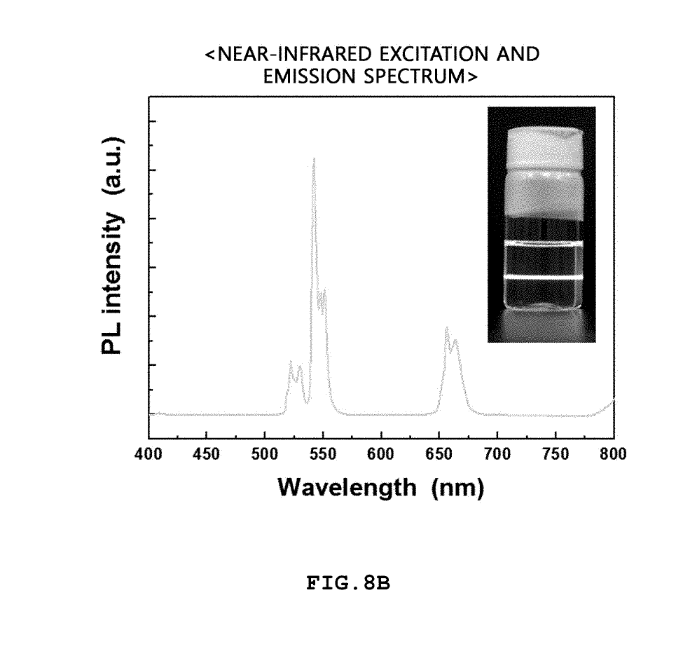

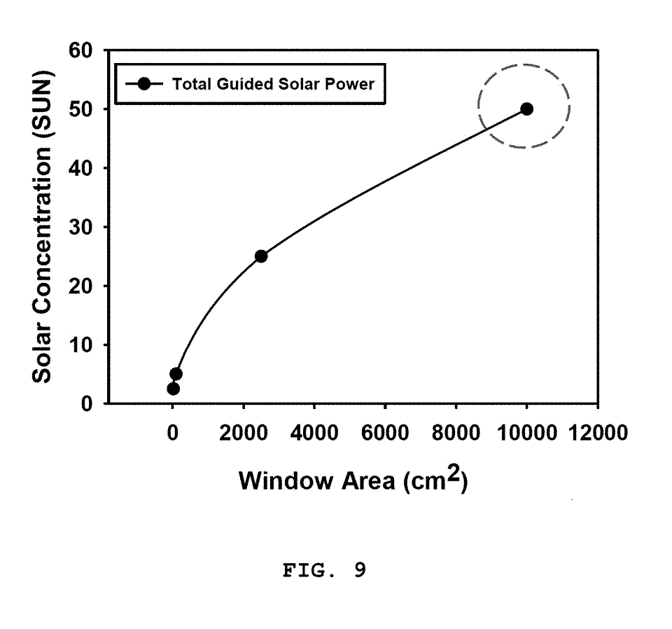

The analysis results of absorption spectrum and emission spectrum of an upconversion material, β-NaYF₄:Yb³⁺/Er³⁺ nanophosphors used in the embodiment of the present disclosure are shown in FIGS. 8A and 8B. According to FIGS. 8A and 8B, it can be seen that sunlight in the infrared range is absorbed and light in the visible range is emitted.

Concentration Ratio on the Side Surface with the Increasing Window Area of the Window Comprising the Solar Cell Panel

FIG. 9 shows a result of calculating a concentration ratio on the side surface with the increasing window area of the window comprising the solar cell panel, when it is assumed that the effective light trapping capacity is 50%.

According to FIG. 9, the concentration ratio on the area of 1 m² is 50 SUN. The infrared upconversion material increases in PL efficiency non-linearly based on the concentration ratio. Generally, the infrared upconversion material absorbs two infrared photons and emits one visible photon, and the PL intensity S increases in proportion to the square or cube of the output P of incident infrared light. Accordingly, as infrared light is concentrated, the intensity of visible light increases rapidly, and as shown in the drawing, the concentration ratio increases with the increasing window area, and accordingly, when the infrared conversion material is positioned on the side surface of the window, the side concentration ratio will be maximized.

While the embodiments of the present disclosure have been hereinabove described, it is obvious to those having ordinary skill in the corresponding technical field that various modifications and changes will be made to the present disclosure by the substitution, alteration, deletion or addition of the elements without departing from the spirit of the present disclosure defined in the appended claims, and such modifications will fall within the scope of protection of the present disclosure.

### DETAILED DESCRIPTION OF MAIN ELEMENTS

100: Light concentration layer
200: Cladding layer
300: Light conversion/light guide layer
310: First light conversion member
312: Reflective layer
314: Light conversion layer
320: Second light conversion member
330: Light guide layer
400: Solar cell array
410: Solar cell
500: Cell frame
510: Insulation layer
520: Conductive layer

What is claimed is:

1. A solar cell panel, comprising:
a light concentration layer on which sunlight is incident and concentrated;
a cladding layer stacked on bottom of the light concentration layer;
a light conversion/light guide layer comprising a light guide layer stacked on bottom of the cladding layer to guide visible light to a side surface, and a light conversion member to convert ultraviolet or infrared light to visible light; and
a solar cell array placed along a side surface of the light conversion/light guide layer, and having multiple solar cells electrically connected.

2. The solar cell panel according to claim 1, wherein the light concentration layer includes any one selected from a convex lens, a concave lens, and a Fresnel lens.

3. The solar cell panel according to claim 1, wherein the cladding layer has a refractive index n of between 1.0 and 1.3.

4. The solar cell panel according to claim 1, wherein the light conversion member comprises:
a first light conversion member to convert ultraviolet light to visible light; and
a second light conversion member to convert infrared light to visible light.

5. The solar cell panel according to claim 4, wherein the first light conversion member is disposed on top or bottom or in the middle of the light guide layer, and comprises:
a light conversion layer including a downconversion material to convert ultraviolet light to visible light; and
a reflective layer stacked on bottom of the light conversion layer or spaced apart from the light conversion layer.

6. The solar cell panel according to claim 5, wherein the light conversion layer is disposed on a focal plane or off the focal plane.

7. The solar cell panel according to claim 5, wherein the reflective layer has a flat structure or an inclined structure.

8. The solar cell panel according to claim 5, wherein the downconversion material is at least one selected from quantum dot, phosphor, and ultraviolet conversion dye.

9. The solar cell panel according to claim 8, wherein the quantum dot is at least one selected from CdZnS/ZnS, CdS, CdSe, CdSe/ZnS, PbS, CdTe, ZnS, ZnSe, ZnTe, GaN, GaP, GaAs, GaSb, AlN, AlP, AlAs, AlSb, InP, InAs, InSb and SiC.

10. The solar cell panel according to claim 8, wherein the phosphor is at least one selected from β-NaYF₄:Yb³⁺/Er³⁺, Y₃Al₅O₁₂:Ce, Y₂SiO₅:Ce³⁺, Sr₂SiO₄:Eu²⁺, Sr₃SiO₅:Eu²⁺, BaMaAl₁₀O₁₇:Eu²⁺, Y₂O₃:Eu³⁺, Y₂O₂S:Eu³⁺, Y₂O₃:Eu³⁺, Bi³⁺, CaMgSi₂O₇:Eu²⁺, SrGa₂S₄:Eu²⁺, Ca-a-SiAlON:Eu²⁺, BaSi₂O₂N₂:Eu²⁺, and CaGa₂S₄:Eu²⁺.

11. The solar cell panel according to claim 4, wherein the second light conversion member is disposed on a side surface of the light guide layer.

12. The solar cell panel according to claim 4, wherein the second light conversion member includes an upconversion material.

13. The solar cell panel according to claim 12, wherein the upconversion material is at least one selected from halide, chalcogenide and metal oxide doped with ytterbium (Yb), erbium (Er), thulium (Tm), yttrium (Y) or mixtures thereof.

14. A window comprising a solar cell panel, comprising:
the solar cell panel according to claim 1; and
a frame connected along edges of the solar cell panel.

15. The window comprising a solar cell panel according to claim 14, wherein the solar cell array is placed on the frame, and the frame is disposed on at least one side surface of the solar cell panel.

16. The window comprising a solar cell panel according to claim 14, wherein the solar cell array placed on the frame has an array of either a series structure or a parallel structure or both.

17. The window comprising a solar cell panel according to claim 14, wherein the frames have an array of either a series structure or a parallel structure or both.
